(19) United States
(12) Patent Application Publication
(10) Pub. No.: US 2002/0059950 A1
(43) Pub. Date: May 23, 2002

(54) Thermoelectric element and fabrication method thereof

(76) Inventors: Yong-Hoon Lee, Hiratsuka (JP); Takeshi Kajihara, Hiratsuka (JP); Kiyoharu Sasaki, Hiratsuka (JP); Akio Konishi, Hiratsuka (JP); Takeji Kajiura, Isehara-Shi (JP); Keisuke Ikeda, Sendai (JP); Susumu Miura, Oyama-shi (JP); Kenichirou Suzuki, Sendai (JP); Mitsuhiro Kuroki, Hiratsuka (JP); Hiroyuki Tokunaga, Hiratsuka (JP); Hiroyuki Mizukami, Nakagun (JP)

Correspondence Address: STEVENS, DAVIS, MILLER & MOSHER, LLP, Suite 850, 1615 L Street, NW, Washington, DC, 20036, US

(21) Appl. No.: 09/817,751

(22) Filed: Mar. 27, 2001

(30) Foreign Application Priority Data
Mar. 28, 2000 (JP) 2000-089043

(51) Int. Cl. H01L 35/00; B22F 1/00; H01L 35/34; H01L 35/16

(52) U.S. Cl. 136/201; 419/67; 136/238; 136/240

(57) ABSTRACT

A method of fabricating a thermoelectric element with a higher thermoelectric performance than that of a conventional thermoelectric element. This fabrication method includes the steps of: (a) preparing a thermoelectric material having a predetermined composition; and (b) applying extruding pressure to the thermoelectric material in a first direction to extrude it through a die having, in an area which is not less than half of a deforming area of the thermoelectric material in the first direction, a maximum strain rate within +30% of an average strain rate so as to plastically deform the thermoelectric material into an extruded product of the thermoelectric material.

### BACKGROUND OF THE INVENTION MERIT

1. Field of the Invention

The present invention relates to a thermoelectric element used on a thermoelectric module and to a method of fabricating such a thermoelectric element.

2. Description of a Related Art

A thermoelectric element refers to an element using thermoelectric effect such as Thomson effect, Peltier effect and Seebeck effect, a thermocouple or an electric refrigeration element and so on. The thermoelectric element with its simple structure, easy handling and capability of maintaining stable characteristics is expected to have a wide range of possible applications. When used as an electric refrigeration element, the thermoelectric element can perform local cooling and accurate temperature control at around room temperature, so a lot of research and development is advanced aiming at the temperature control of optoelectronics and semiconductor lasers and application to small refrigerator; etc.

A thermoelectric module including such thermoelectric elements has a construction in which, as shown in FIG. 9, between two ceramic substrates 30 and 40, P-type elements (P-type semiconductors) 50 and N-type elements (N-type semiconductors) 60 are connected through electrodes 70 to form PN element pairs, which are connected in series. An N-type element at one end of the serial circuit of the PN element pairs is connected with a current introducing terminal of a positive pole 80 and a P-type element at the other end is connected with a current introducing terminal of a negative pole 90. By applying a voltage between these current introducing terminals 80 and 90, current flows from the current introducing terminal of the positive pole 80 through the serial circuit of PN element pairs to the current introducing terminal of the negative pole 90, which current causes cooling the ceramic substrate 30 and heating the ceramic substrate 40. This produces a thermal flow in the direction of arrow as shown in FIG. 9.

A figure of merit Z which represents performance of the thermoelectric element is defined as Z=α²/ρκ. Where, α, ρ and κ denote a Seebeck coefficient, an electrical resistivity and a thermal conductivity, respectively. It is desired that the thermoelectric element has a figure of merit Z as large as possible.

Japanese patent application publications JP-A-63-138789, JP-A-8-186299 and JP-A-10-56210 disclose enhancing a figure of merit by applying an extruding process, which is one kind of plastic deformation process, on the thermoelectric material.

These publications, however, do not give details concerning extrusion conditions.

### SUMMARY OF THE INVENTION

In view of the above, the object of this invention is to clarify the shape of a deforming area included in die used in the extruding process of the thermoelectric material and thereby provide a thermoelectric element with a higher thermoelectric conversion efficiency than that of the conventional thermoelectric element.

To achieve the above object, a method of fabricating a thermoelectric element according to a first aspect of the invention comprises the steps of: (a) preparing a thermoelectric material having a predetermined composition; and (b) applying extruding pressure to the thermoelectric material in a first direction to extrude it through a die having, in an area which is not less than half of a deforming area of the thermoelectric material in the first direction, a maximum strain rate within +30% of an average strain rate so as to plastically deform the thermoelectric material into an extruded product of the thermoelectric material.

Further, a method of fabricating a thermoelectric element according to a second aspect of the invention comprises the steps of: (a) preparing a thermoelectric material having a predetermined composition; and (b) applying extruding pressure to the thermoelectric material in a first direction to extrude it through a die by keeping a strain rate in the first direction of the thermoelectric material substantially constant in an area which is not less than half of a deforming area and preventing the thermoelectric material from being deformed in a second direction perpendicular to the first direction but allowing it to be deformed in a third direction perpendicular to the first and second directions so as to produce a rectangular parallelepiped product of the thermoelectric material.

The thermoelectric element according to this invention is manufactured by the fabricating method described above.

According to the present invention, the figure of merit Z can be improved by the variation of the value of the Seebeck coefficient α or the resistivity ρ of the thermoelectric element by making the crystal grain of the thermoelectric material finely and decreasing the residual strain.

### BRIEF DESCRIPTION OF THE DRAWINGS

FIG. 1 shows a flow chart of fabricating method of a thermoelectric element according to one embodiment of the invention.

FIG. 2 shows a schematic diagram of an extrusion apparatus used in the thermoelectric element fabrication method according to one embodiment of the invention.

FIG. 3 shows a perspective view of a planar strain extrusion die used in one embodiment of the invention.

FIG. 4 is a graph showing a comparison in cross-sectional shapes of a planar strain extrusion die between an example of the invention and a comparative example for an extrusion ratio of 5.

FIG. 5 is a graph showing a comparison in cross-sectional shapes of a planar strain extrusion die between an example of the invention and a comparative example for an extrusion ratio of 15.

FIG. 6 is a graph showing a comparison in strain rate changes between an example of the invention and a comparative example for an extrusion ratio of 5.

FIG. 7 is a graph showing a comparison in strain rate changes between an example of the invention and a comparative example for an extrusion ratio of 15.

FIG. 8 is a table showing a property comparison between extruded products actually fabricated by extruding the thermoelectric material with the planar strain extrusion dies of the examples of the invention and the planar strain extrusion dies of a comparative examples.

FIG. 9 is a diagram schematically showing a structure of a thermoelectric module including thermoelectric elements.

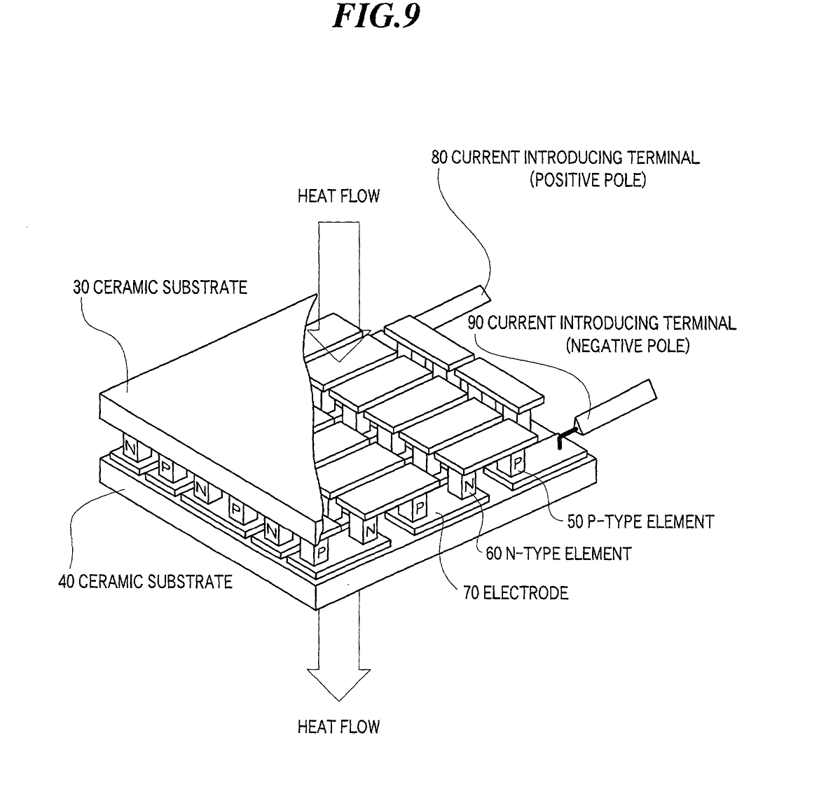

### DESCRIPTION OF THE PREFERRED EMBODIMENTS

Now, embodiments of the present invention will be described by referring to the accompanying drawings. Identical constitutional elements are given like reference numbers and their repetitive explanations omitted.

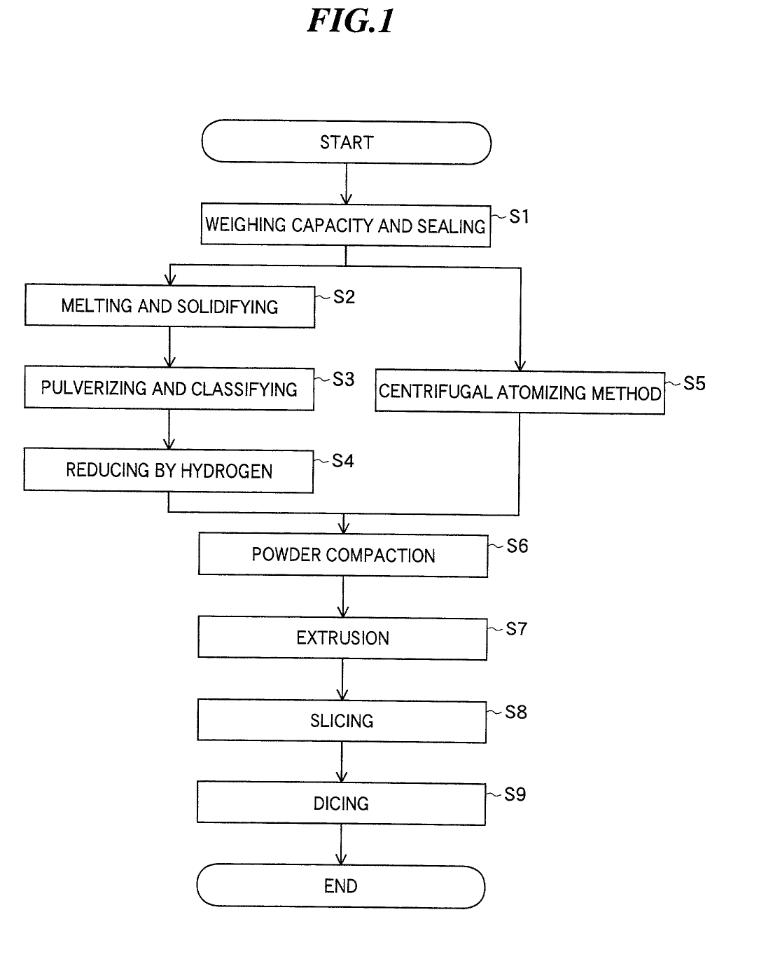

FIG. 1 is a flow chart showing the process of fabricating the thermoelectric element according to one embodiment of the invention.

First, at step S1, a predetermined amount of raw materials of a predetermined composition is measured and sealed in a glass ampoule. The raw materials for thermoelectric material include, for example, antimony (Sb) and bismuth (Bi) as V-group elements and selenium (Se) and tellurium (Te) as VI-group elements. A solid solution of the V-group element and the VI-group element has a hexagonal structure. As for the detailed compositions of the thermoelectric materials, a P-type element may be made from P-type dopant doped mixed crystal solid solution of bismuth telluride (Bi₂Te₃) and antimony telluride (Sb₂Te₃), and a N-type element may be made from N-type dopant doped mixed crystal solid solution of bismuth telluride (Bi₂Te₃) and bismuth selenide (Bi₂Se₃).

Next, at step S2, the raw materials sealed in the container are heated to melt and then the molten material is solidified by, for example, uni-directional solidification to form a solid solution as the thermoelectric material. Next, at step S3, the thermoelectric material is pulverized by a stamp mill or ball mill to form powder of thermoelectric material. The powder is classified according to grain diameter. For example, the powder is passed through sieves of 150 and 400 mesh and the powder remaining on the 400-mesh sieve is classified so that the grain diameters are between 34 and 108 Next, at step S4, the powder is fed into a glass ampoule of a predetermined capacity, which is then evacuated, injected with hydrogen at 0.9 atmosphere and sealed. The ampoule is heated at 350° C. for 10 hours in a furnace to cause the surface of powder to be hydrogen-reduced. This step S4 may be omitted. Instead of performing the steps S2-S4 above, it is possible to form powder of thermoelectric material by the centrifugal atomizing method as shown in step S5.

At step S6 following step S4 or S5, the powder compaction is performed by a cold press or a hot press. At this time, a mold of a same shape as a die (extrusion mold) may be used. In that case, a process of cutting the molding material to the size of the die can be omitted.

Next, at step S7, the powder-compacted thermoelectric material is extruded. Then, at step S8, the extruded thermoelectric material is sliced and, at step S9, the sliced material is diced to form thermoelectric elements of a desired size.

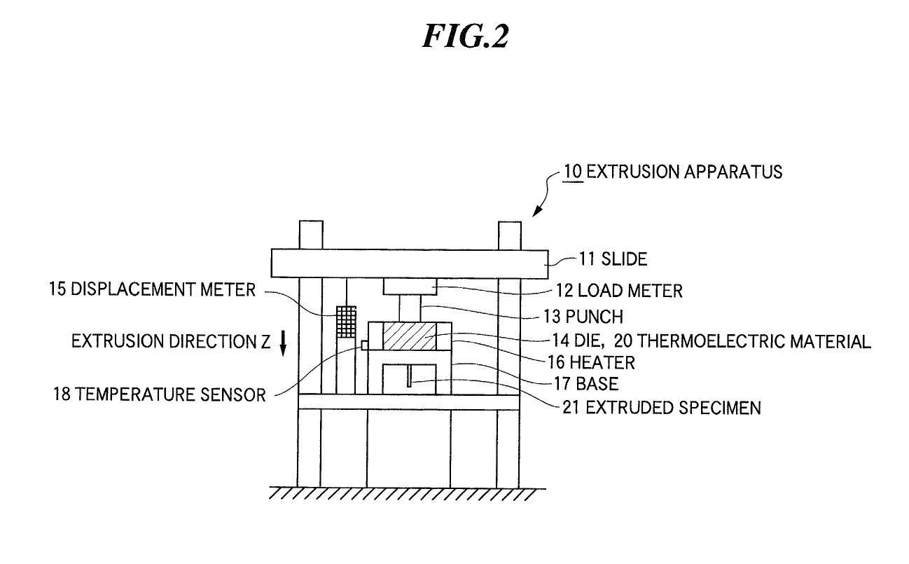

The extrusion process (step S7) above will be explained in detail with reference to FIG. 2.

FIG. 2 shows an extrusion apparatus used in the method of fabricating the thermoelectric element according to one embodiment of the invention. As shown in FIG. 2, the extrusion apparatus 10 includes a punch 13, which is a mold for extruding the powder-molded thermoelectric material 20, and a die (extrusion mold) 14 for plastically deforming the thermoelectric material 20 as it is extruded by the punch 13. A slide 11 is driven, for example, by a hydraulic actuator (hydraulic cylinder) to move the punch 13 vertically. An extrusion pressure of the punch 13 is measured by a load meter 12 and a displacement of the punch 13 in the extrusion direction Z is measured by a displacement meter 15. By monitoring the relation between the measured value of the displacement meter 15 and the elapsed time, the slide 11 can be controlled to cause the punch 13 to extrude the thermoelectric material 20 at a constant extrusion rate.

On a base 17, the die 14 and a heater 16 are installed, which the heater 16 surrounds the die 14. With this arrangement, the extrusion apparatus 10 can also serve as a heating device. The temperature of the die 14 is measured by a temperature sensor 18 arranged near the die 14. A measured value of the temperature sensor 18 is fed back to control the amount of heat produced by the heater 16 and thereby keep the die 14 and the thermoelectric material 20 at a desired temperature.

The thermoelectric material 20, as it is extruded by the punch 13 through the die 14, is plastically deformed into an extruded sample (an extruded specimen) 21. It is preferred that the extrusion is performed in an inert gas atmosphere or in a vacuum while processing temperature is controlled to be 350-600° C. Although in this embodiment the punch 13 is moved while the die 14 is fixed, this may be reversed, that is, the die 14 is moved while the punch 13 is fixed.

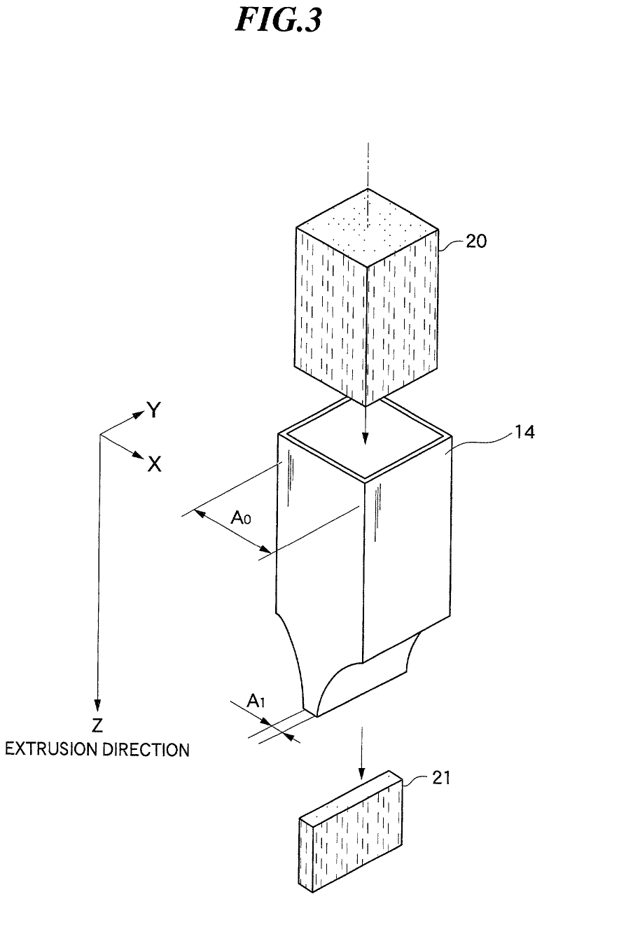

It is found that the figure of merit of the thermoelectric element obtained by slicing and dicing the extruded sample varies greatly with the shape of the die and the way of the surface treatment. Preferred conditions affecting the figure of merit will be explained with reference to FIG. 3 to FIG. 8.

FIG. 3 is a perspective view of a planar strain extrusion die used in this embodiment. The planar strain extrusion die 14 has a constant width spanning in the Y-direction perpendicular to the direction of extrusion (Z-direction) and has its thickness throttled in the X-direction perpendicular to both the Z and the Y directions. In FIG. 3, the thickness of the planar strain extrusion die 14 on the inlet side (inner diameter) is denoted A₀ and the thickness on the outlet side (inner diameter) is denoted A₁. The extrusion ratio is defined as A₀/A₁. The strain rate of the thermoelectric material 20 during the plastic deformation greatly varies depending on a shape of the curved portion of the planar strain extrusion die 14 where the inner diameter decreases from A₀ to A₁. The strain rate is defined as an amount of strain produced per unit time and is determined as follows.

First, a strain e(z) for a distance z in the extrusion direction (Z-direction) is determined.

ε(z)=dx/x(z)=x′(z)/x(z)·dz

where x(z) represents a half of the inner diameter of the die including its inner surface in a direction (X-direction) perpendicular to the extrusion direction.

Next, a total strain ε is generally defined as follows.

$$\begin{matrix}ϵ = {\int }_{{z}_{0}}^{{z}_{1}} ϵ ( z ) \\ = {\int }_{{z}_{0}}^{{z}_{1}} \frac{{x}^{′} ( z )}{x ( z )} ⅆ z \\ = {[ ln ( x ( z ) ) ]}_{{z}_{0}}^{{z}_{1}} \\ = ln \frac{x ( {z}_{1} )}{x ( {z}_{0} )}\end{matrix}$$

where z₀ represents a distance in the Z-direction when the extrusion starts, and z₁ represents a distance in the Z-direction when the extrusion ends. The total strain ε therefore is determined by the inner diameter of the die at the start of the extrusion and the inner diameter of the die at the end of the extrusion and does not depend on the shape of the intermediate part of the die.

If it is assumed that there is no volume change of the compound and that the strain in the X-direction is constant, then the strain in the Z-direction has the similar strain ratio. That is, if we let the position in the X-direction of the die at the start of the extrusion be x₀, then the following relationship holds:

z₀·x₀=z·x=(constant)

Hence, the relationship between the strain in the Z-direction ε_{Z} and the strain in the X-direction ε_{X} is given as follows.

ε_{Z}=ln(z/z₀)=ln(x₀/x)=−ε_{X}

In this way, the strain in the Z-direction ε_{Z} and the strain in the X-direction ε_{X} are equal in the absolute value but with opposite signs of strain direction.

Next, the strain rate ε′ is defined as

$${ϵ}^{′} = \frac{ⅆ ϵ}{ⅆ t} = \sqrt{\frac{2}{3} ( {ϵ}_{x}^{{′}^{2}} + {ϵ}_{y}^{{′}^{2}} + {ϵ}_{z}^{{′}^{2}} )}$$

For example, when ε′_{y}=0 and ε′_{z}=−ε′ₓ,

$${ϵ}^{′} = \frac{2}{\sqrt{3}} {ϵ}_{x}^{′}$$

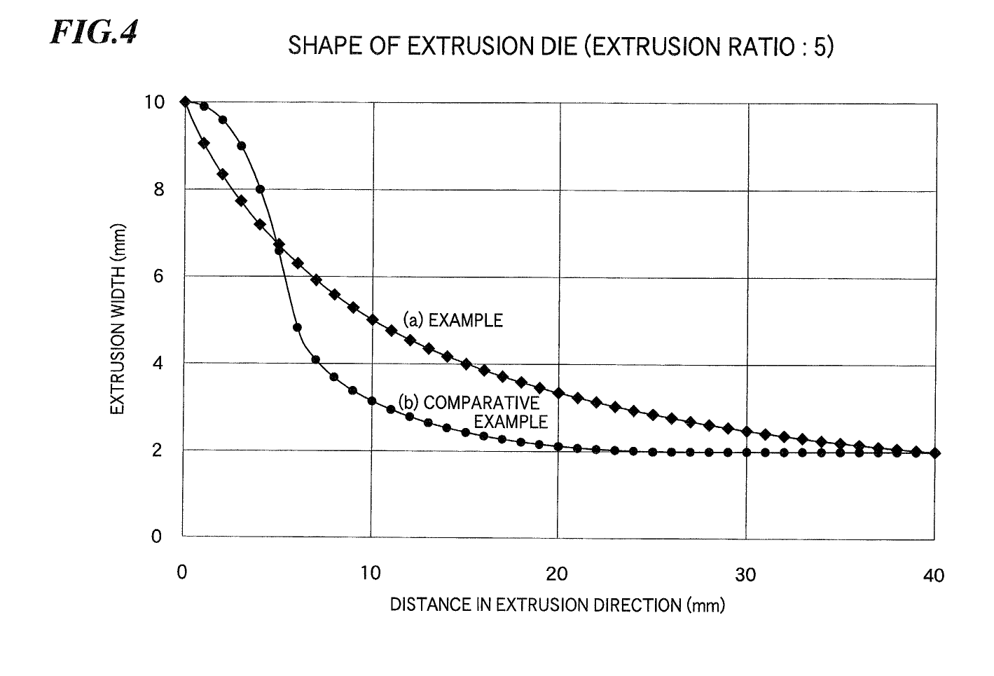

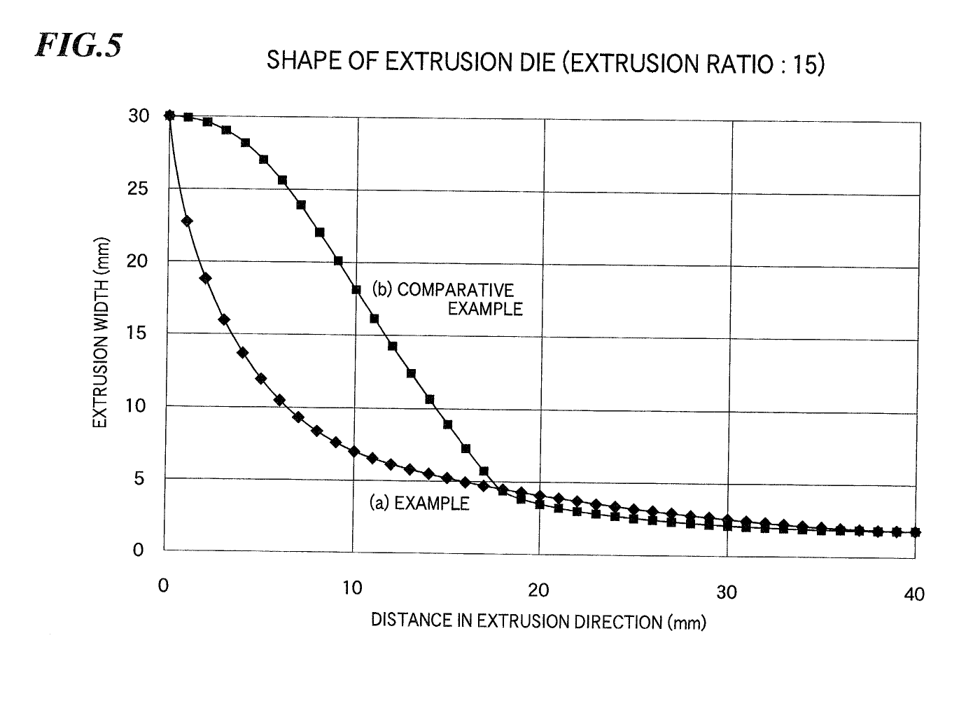

FIG. 4 compares the cross-sectional shape (a) of a planar strain extrusion die of an example and the cross-sectional shape (b) of a planar strain extrusion die of a comparative example for the extrusion ratio of 5. FIG. 5 compares the cross-sectional shape (a) of a planar strain extrusion die of an example and the cross-sectional shape (b) of a planar strain extrusion die of a comparative example for the extrusion ratio of 15. In FIG. 4 and FIG. 5 the abscissa represents a distance in the extrusion direction (Z-direction), the ordinate represents the extrusion width (a distance in the X-direction from the extrusion axis) and the deforming area of the die is set between 0 and 40 mm.

As shown in the curved lines (a) in FIG. 4 and FIG. 5, the cross-sectional shape of the die has a shape of a hyperbola from the deforming area to the outlet. As shown in the curved lines (b) in FIG. 4 and FIG. 5, however, the cross-sectional shape of the die has a shape of a combination of ellipse and straight line from the deforming area to the outlet.

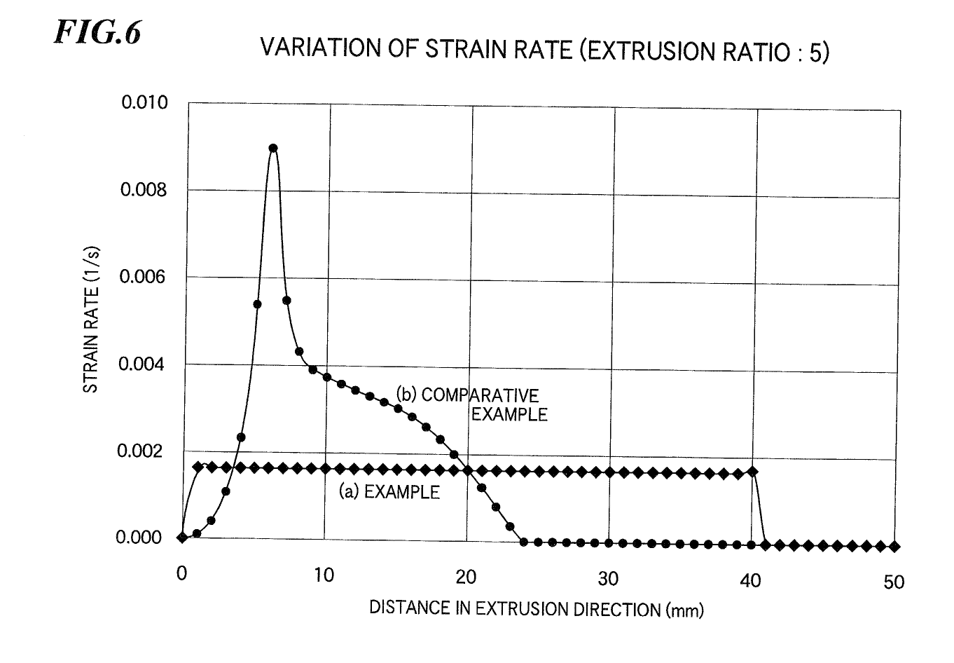

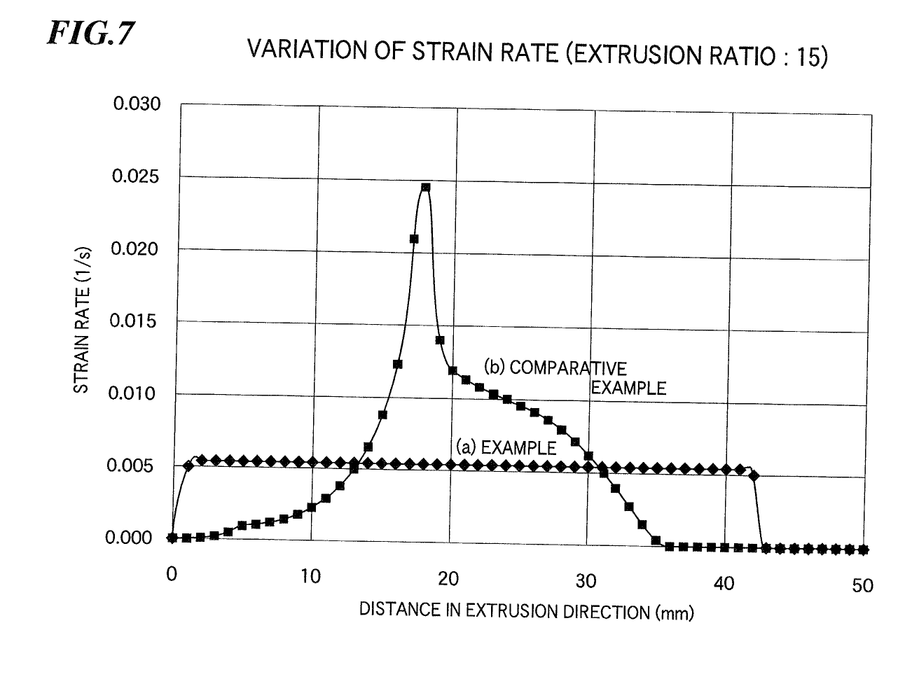

FIG. 6 shows variation of the strain rate for the extrusion ratio of 5 when the planar strain extrusion dies of the example and the comparative example are used. FIG. 7 shows variation of the strain rate for the extrusion rate of 15 when the planar strain extrusion dies of the example and the comparative example are used. In FIG. 6 and FIG. 7, the abscissa represents a distance in the extrusion direction (Z-direction), the ordinate represents the extrusion rate of the thermoelectric material and the extrusion rate is set at 1 mm/min.

As shown in FIG. 6 and FIG. 7, in the case of the example, the strain rate is virtually constant in most, or at least a half, in the deforming area. In this application, it is defined that the strain rate is virtually constant when the strain rate is in the range from the maximum value to 95% of the maximum value. In more general terms, this invention is characterized in that, in the half or more of the deforming area, the maximum value of the strain rate of the thermoelectric material is within +30% of the average of the strain rate.

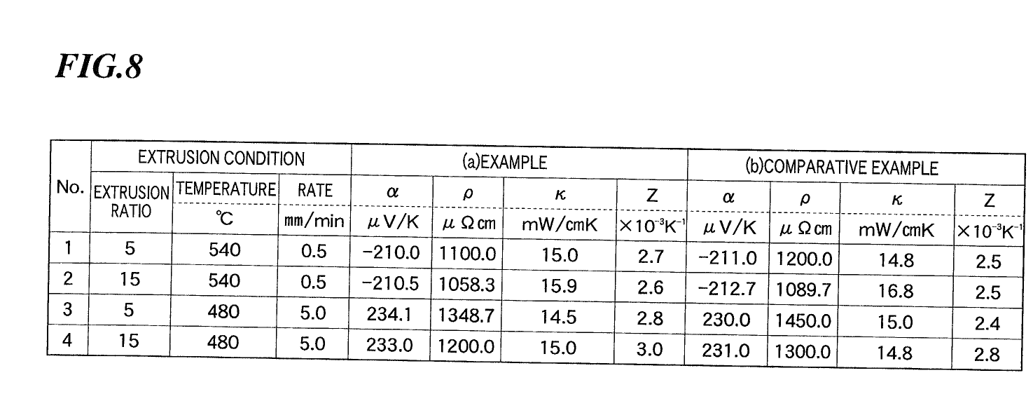

FIG. 8 is a table comparing the properties of the extruded products fabricated by actually extruding the thermoelectric material through the planar strain extrusion dies of the examples and the comparative examples. Here, the sintered sample which prepared by using quenched and solidified powder was extruded. Specimen No. 1 and No. 2 are N-type thermoelectric elements and specimen No. 3 and No. 4 are P-type thermoelectric elements. As shown in FIG. 8, the extruded product of the examples are considered to have reduced residual strains, which in turn reduce the resistivity ρ resulting in a higher figure of merit Z than that of the comparative examples.

These dies are surface-treated to form a thin film of TiCrN or TiAlN. The thin film increases the strength of the dies and ensures smooth extrusion. Although this embodiment uses the planar strain extrusion die, the present invention can also be applied where a round bar of thermoelectric material is extruded through a round die to form a round bar-like extruded product.

As described above, the present invention can change the Seebeck coefficient α or resistivity ρ of the thermoelectric element and thereby improve the figure of merit Z by improving the crystal orientation of the thermoelectric element and reducing the grain size and the residual strain. As a result, the thermoelectric element with higher thermoelectric performance can be provided.

1. A method of fabricating a thermoelectric element comprising the steps of:
(a) preparing a thermoelectric material having a predetermined composition; and
(b) applying extruding pressure to said thermoelectric material in a first direction to extrude it through a die having, in an area which is not less than half of a deforming area of said thermoelectric material in the first direction, a maximum strain rate within +30% of an average strain rate so as to plastically deform said thermoelectric material into an extruded product of said thermoelectric material.

2. A method according to claim 1, wherein step (b) includes applying extruding pressure to a round bar of said thermoelectric material in an axial direction to extrude it through said die to plastically deform said thermoelectric material into a round bar like extruded product.

3. A method according to claim 1, wherein step (a) includes applying pressure to powder of said thermoelectric material to form one of a green compact and a sintered compact of said thermoelectric material.

4. A method according to claim 1, wherein said thermoelectric material includes at least two kinds of chemical elements of Bi, Te, Sb and Se.

5. A method according to claim 1, wherein step (b) includes applying extruding pressure to said thermoelectric material in one of an air, an inert gas atmosphere and a vacuum to extrude it through said die.

6. A method according to claim 1, wherein step (b) includes applying extruding pressure to said thermoelectric material while keeping processing temperature at 350-600° C. to extrude it through said die.

7. A method of fabricating a thermoelectric element comprising the steps of:
(a) preparing a thermoelectric material having a predetermined composition; and
(b) applying extruding pressure to said thermoelectric material in a first direction to extrude it through a die by keeping a strain rate in the first direction of said thermoelectric material substantially constant in an area which is not less than half of a deforming area and preventing said thermoelectric material from being deformed in a second direction perpendicular to the first direction but allowing it to be deformed in a third direction perpendicular to said first and second directions so as to produce a rectangular parallelepiped product of said thermoelectric material.

8. A method according to claim 7, wherein step (a) includes applying pressure to powder of said thermoelectric material to form one of a green compact and a sintered compact of said thermoelectric material.

9. A method according to claim 7, wherein said thermoelectric material includes at least two kinds of chemical elements of Bi, Te, Sb and Se.

10. A method according to claim 7, wherein step (b) includes applying extruding pressure to said thermoelectric material in one of an air, an inert gas atmosphere and a vacuum to extrude it through said die.

11. A method according to claim 7, wherein step (b) includes applying extruding pressure to said thermoelectric material while keeping processing temperature at 350-600° C. to extrude it through said die.

12. A thermoelectric element fabricated by a fabrication method, said fabrication method comprising the steps of:
(a) preparing a thermoelectric material having a predetermined composition; and
(b) applying extruding pressure to said thermoelectric material in a first direction to extrude it through a die having, in an area which is not less than half of a deforming area of said thermoelectric material in the first direction, a maximum strain rate within +30% of an average strain rate so as to plastically deform said thermoelectric material into an extruded product of said thermoelectric material.

13. A thermoelectric element according to claim 12, wherein step (a) includes applying pressure to powder of said thermoelectric material to form one of a green compact and a sintered compact of said thermoelectric material.

14. A thermoelectric element according to claim 12, wherein said thermoelectric material includes at least two kinds of chemical elements of Bi, Te, Sb and Se.

15. A thermoelectric element according to claim 12, wherein step (b) includes applying extruding pressure to said thermoelectric material in one of an air, an inert gas atmosphere and a vacuum to extrude it through said die.

16. A thermoelectric element according to claim 12, wherein step (b) includes applying extruding pressure to said thermoelectric material while keeping the processing temperature at 350-600° C. to extrude it through said die.

17. A thermoelectric element fabricated by a fabrication method, the fabrication method comprising the steps of:
(a) preparing a thermoelectric material having a predetermined composition; and
(b) applying extruding pressure to said thermoelectric material in a first direction to extrude it through a die by keeping a strain rate in the first direction of said thermoelectric material substantially constant in an area which is not less than half of a deforming area and preventing said thermoelectric material from being deformed in a second direction perpendicular to the first direction but allowing it to be deformed in a third direction perpendicular to said first and second directions so as to produce a rectangular parallelepiped product of said thermoelectric material.

18. A thermoelectric element according to claim 17, wherein step (a) includes applying pressure to powder of said thermoelectric material to form one of a green compact and a sintered compact of said thermoelectric material.

19. A thermoelectric element according to claim 17, wherein said thermoelectric material includes at least two kinds of chemical elements of Bi, Te, Sb and Se.

20. A thermoelectric element according to claim 17, wherein step (b) includes applying extruding pressure to said thermoelectric material in one of an air, an inert gas atmosphere and a vacuum to extrude it through said die.

21. A thermoelectric element according to claim 17, wherein step (b) includes applying extruding pressure to said thermoelectric material while keeping processing temperature at 350-600° C. to extrude it through said die.
